(19) United States
(12) Patent Application Publication
(10) Pub. No.: US 2024/0258361 A1
(43) Pub. Date: Aug. 1, 2024

(54) QUANTUM DOT HYBRID INTEGRATED MULTI-COLOR DISPLAY AND MANUFACTURING METHOD THEREFOR

(71) Applicant: SEMICONDUCTOR INTEGRATED DISPLAY TECHNOLOGY CO., LTD., Anhui Province (CN)

(72) Inventors: Shiwei WANG, Anhui Province (CN); Benpei ZHENG, Anhui Province (CN); Chengyuan LIU, Anhui Province (CN); Luyang FENG, Anhui Province (CN); Shengfang LIU, Anhui Province (CN); Zhengtao ZHAO, Anhui Province (CN)

(21) Appl. No.: 18/423,645

(22) Filed: Jan. 26, 2024

(30) Foreign Application Priority Data
Jan. 31, 2023 (CN) 202310048013 .5

(51) Int. Cl. H01L 27/15; H01L 33/42; H01L 33/44; H01L 33/50; H01L 33/52; H01L 33/60

(52) U.S. Cl. CPC H01L 27/156; H01L 33/42; H01L 33/44; H01L 33/502; H01L 33/52; H01L 33/60; H01L 2933/0016; H01L 2933/0041; H01L 2933/005; H01L 2933/0058

(57) ABSTRACT

Disclosed is a quantum dot hybrid integrated multi-color display, including a CMOS wafer substrate, anode vias, and a light-emitting unit. Tungsten holes are formed in the CMOS wafer substrate, the anode vias are formed in the CMOS wafer substrate, and the anode vias are electrically connected with a driving circuit in the CMOS wafer substrate through the tungsten holes. The anode vias are blind vias starting on a surface of the CMOS wafer substrate. The light-emitting unit is disposed on the surface of the anode via in the CMOS wafer substrate, a driving current signal is provided to the light-emitting unit through the anode via.

### CROSS REFERENCE TO RELATED APPLICATION

This application claims priority to Chinese patent application Ser. No. 202310048013.5, filed on Jan. 31, 2023. The entire disclosure of the above application is incorporated herein by reference.

### TECHNICAL FIELD

The disclosure belongs to the technical field of microdisplay, and particularly relates to a quantum dot hybrid integrated multi-color display and a manufacturing method therefor.

### BACKGROUND

A microdisplay is a visual gateway to a currently popular “meta universe” concept. At present, liquid crystal on silicon (LCOS) is the mainstream technology of the microdisplay. A liquid crystal display (LCD) realizes display by the switch of liquid crystal, however, a response speed of the liquid crystal is slow, and it is difficult to achieve high resolution, so there are shortcomings such as screen door effect, and it is not suitable for long-term wear in the application of the leading “meta-universe. Micro-OLED, i.e., the OLED-on-silicon technology, has the disadvantages of low brightness and low luminous efficiency, although it is currently in mass production. Micro-LED is considered to be the most suitable microdisplay for “meta-universe” applications. However, its colorization is still a problem difficult to solve at present. Micro-LED microdisplay, whether applied to conventional display or high-pixel-per-inch (PPI) microdisplay, has a technical disadvantage that the manufacturing process is complicated, resulting in a low product manufacturing yield, which is not suitable for mass production.

A search revealed that Chinese invention patent No. CN201910816511, published on Dec. 13, 2019, disclosed a display device based on a phase change material and quantum dots including a display unit. The display unit includes a multi-color quantum dot backlight source and a phase change filter. The multi-color quantum dot backlight source includes a substrate and a multi-color quantum dot light-emitting assembly disposed on a top surface of the substrate and configured to emit a polychromatic light. The phase change filter includes an isolation layer, a first F-P resonant cavity, a phase change material layer, and a second F-P resonant cavity which are sequentially disposed from bottom to top. A voltage is applied to the phase change material layer for electrical stimulation or the phase change material layer is irradiated with laser for laser stimulation, and polychromatic light emitted by the multi-color quantum dot light-emitting assembly is filtered by utilizing a change in transmittance of the phase change material layer during mutual conversion between an amorphous state and a crystalline state, so that monochromatic light with a desired wavelength and intensity is obtained, and color display is further realized. However, the lifetime and efficiency of the material of blue light in quantum dot polychromatic light still cannot meet the requirements of production cost and performance, and the above technical problem cannot be solved.

### SUMMARY

Embodiments of the disclosure provide a quantum dot hybrid integrated multi-color display which is simple in structure, convenient in use, high in manufacturing yield, and good in luminous effect, and a manufacturing method for a quantum dot hybrid integrated multi-color display which is simple in process and easy to implement. In the embodiments of the disclosure, the problem of micro-LED colorization and the disadvantages of immature technology about the lifetime and efficiency of quantum dot blue material are avoided by using quantum dots in combination with blue LEDs.

A quantum dot hybrid integrated multi-color display provided by embodiments of the disclosure, includes a CMOS wafer substrate, anode vias and a light-emitting unit. Tungsten holes are formed in the CMOS wafer substrate, the anode vias are formed in the CMOS wafer substrate, and the anode vias are electrically connected with a driving circuit in the CMOS wafer substrate through the tungsten holes. The anode vias are blind vias that start on a surface of the CMOS wafer substrate. The light-emitting unit is disposed on the surface of the anode via in the CMOS wafer substrate, and a driving current signal is provided to the light-emitting unit through the anode via.

In some embodiments, the quantum dot hybrid integrated multi-color display further includes a filling layer and a cover glass, the filling layer is formed by OC glue and coats a surface of the CMOS wafer substrate and a surface of the light-emitting unit, and the cover glass is used to seal the whole device.

In some embodiments, the light-emitting unit includes an LED blue light-emitting unit, a quantum dot first light-emitting unit and a quantum dot second light-emitting unit, and the quantum dot first light-emitting unit is configured to emit a green light and the quantum dot second light-emitting unit is configured to emit a red light, or the quantum dot first light-emitting unit is configured to emit a red light and the quantum dot second light-emitting unit is configured to emit a green light; or only the quantum dot first light-emitting unit and the LED blue light-emitting unit are arranged to jointly form a two-color light-emitting unit, and the quantum dot first light-emitting unit is configured to emit a green light or red light; or only the quantum dot second light-emitting unit and the LED blue light-emitting unit are arranged to jointly form a two-color light-emitting unit, and the quantum dot second light-emitting unit is configured to emit a green light or red light.

In some embodiments, the quantum dot first light-emitting unit includes an anode of the first light-emitting unit, a hole injection layer of the first light-emitting unit, a hole transport layer of the first light-emitting unit, a quantum dot first light-emitting layer, an electron transport layer of the first light-emitting unit, and a cathode layer of the first light-emitting unit which are sequentially disposed from bottom to top. The quantum dot second light-emitting unit includes an anode of the second light-emitting unit, a hole injection layer of the second light-emitting unit, a hole transport layer of the second light-emitting unit, a quantum dot second light-emitting layer, an electron transport layer of the second light-emitting unit, and a cathode layer of the second light-emitting unit which are sequentially disposed from bottom to top.

In some embodiments, the LED blue light-emitting unit, the quantum dot first light-emitting unit and the quantum dot second light-emitting unit are respectively arranged on surfaces of the anode vias which are formed side by side in the CMOS wafer substrate, and a spacing is formed between the LED blue light-emitting unit, the quantum dot first light-emitting unit and the quantum dot second light-emitting unit.

In some embodiments, a transparent conductive thin film ITO is deposited on the whole CMOS wafer substrate and the LED blue light-emitting unit, the quantum dot first light-emitting unit, and the quantum dot second light-emitting unit to form a common cathode; and one or more of metals Mg, Ag, Au, Al, Cu, Cr, and Ti are deposited on a surface of the transparent conductive thin film ITO in a region between the LED blue light-emitting unit, the quantum dot first light-emitting unit, and the quantum dot second light-emitting unit to form one or more metal layers to form interconnecting electrodes.

Based on the above quantum dot hybrid integrated multi-color display, the disclosure also provides a manufacturing method for the quantum dot hybrid integrated multi-color display, including:
S1: providing a CMOS wafer substrate and a blue LED epitaxial wafer, performing metal bonding on the CMOS wafer substrate and the blue LED epitaxial wafer, removing an LED epitaxial wafer substrate, and performing pixel patterning through photoetching and etching to form a silicon-based CMOS wafer with a blue light-emitting unit; and etching a metal on a surface of the CMOS wafer by an ion beam etching (IBE) process, and leaving only metals located at positions of an LED blue light-emitting unit, a quantum dot first light-emitting unit, and a quantum dot second light-emitting unit, where each light-emitting unit has a size of 0.1 μm-30 μm, and a spacing between the light-emitting units is 0.01 μm-5 μm;
S2: depositing ITO by a sputter process, and forming an ITO layer above metals at positions where the quantum dot first light-emitting unit and the quantum dot second light-emitting unit are located by photo and etching;
S3: depositing PEDOT:PSS on the surface of the ITO layer by a solution spin coating method or a vacuum evaporation process to form a hole injection layer having a thickness of 30 nm;
S4: depositing TFB on the hole injection layer by a solution spin coating method or a vacuum evaporation process to form a hole transport layer having a thickness of 30 nm;
S5: depositing DICTRz:CdSe/CdS quantum dots (red quantum dots having an emission wavelength of 630 nm) at a position of the quantum dot first light-emitting unit or a position of the quantum dot second light-emitting unit on the hole transport layer by a solution spin coating method or a vacuum evaporation process to form a quantum dot light-emitting layer having a thickness of 40 nm;
S6: depositing CdSe/CdS or InP quantum dots (green quantum dots having an emission wavelength of 540 nm) at a position of the quantum dot second light-emitting unit or a position of the quantum dot first light-emitting unit on the hole transport layer by a solution spin coating method or a vacuum evaporation process to form a quantum dot light-emitting layer having a thickness of 40 nm;
S7: depositing ZnO on the light-emitting layer by a solution spin coating method or a vacuum evaporation process to form an electron transport layer having a thickness of 30 nm;
S8: removing substances deposited in subsequent steps from S2 on the surface of the LED blue light-emitting unit by photoetching and an organic solvent chemical etching method, and synchronously removing deposited substances between the LED blue light-emitting unit, the quantum dot first light-emitting unit, and the quantum dot second light-emitting unit, thereby forming the quantum dot first light-emitting unit and the quantum dot second light-emitting unit; and
S9: depositing a transparent conductive thin film ITO having a thickness of 20 nm-1000 nm on the whole CMOS wafer substrate and the LED blue light-emitting unit, the quantum dot first light-emitting unit, and the quantum dot second light-emitting unit by adopting a sputter process to form a common cathode.

In some embodiments, the LED blue light-emitting unit is disposed on a surface of the anode via in the CMOS wafer substrate, a passivation layer is deposited on a side wall of the LED blue light-emitting unit by plasma enhanced chemical vapor deposition (PECVD) or atomic layer deposition (ALD), the quantum dot first light-emitting unit and the quantum dot second light-emitting unit are disposed above the LED blue light-emitting unit, and a spacing is formed between the quantum dot first light-emitting unit and the quantum dot second light-emitting unit.

In some embodiments, one or more of ITO, Mg, Ag, Au, Al, Cu, Cr, Ti, and Ni are deposited on a top surface of the LED blue light-emitting unit to form a transparent cathode layer for the LED blue light-emitting unit, one or more of DBR, ODR, Mg, Ag, Au, Al, Cu, Cr, Ti, and Ni are deposited on a surface of the cathode layer as a reflective layer, a length of the reflective layer is less than a length of the LED blue light-emitting unit, the quantum dot first light-emitting unit and the quantum dot second light-emitting unit are located on a top surface of the reflective layer, and an anode of the quantum dot first light-emitting unit and an anode of the quantum dot second light-emitting unit are respectively electrically connected with the anode vias in the CMOS wafer substrate.

In some embodiments, one or more of ITO, Mg, Ag, Au, Al, Cu, Cr, Ti, and Ni of 0.5 μm-2 μm are deposited on a top surface of a periphery of the LED blue light-emitting unit to form a cathode of the LED blue light-emitting unit, and reflective lenses are respectively arranged on left and right sides of the LED blue light-emitting unit; and a transparent conductive thin film ITO is deposited on the whole CMOS wafer substrate and the quantum dot first light-emitting unit, the quantum dot second light-emitting unit, and the cathode of the LED blue light-emitting unit as a common cathode, and one or more of metals Mg, Ag, Au, Al, Cu, Cr, and Ti are deposited on a surface of the transparent conductive thin film ITO between the quantum dot first light-emitting unit and the quantum dot second light-emitting unit to form one or more metal layers to form interconnecting electrodes.

Based on the above quantum dot hybrid integrated multi-color display, embodiments of the disclosure further provide a manufacturing method for the quantum dot hybrid integrated multi-color display, including:
S21: providing a CMOS wafer substrate and a blue LED epitaxial wafer, performing metal bonding on the CMOS wafer substrate and the blue LED epitaxial wafer, removing an LED epitaxial wafer substrate, and performing pixel patterning through photoetching and etching to form a silicon-based CMOS wafer with a blue light-emitting unit; etching a metal on a surface of the CMOS wafer by an IBE process, and leaving a metal located in the LED blue light-emitting unit; and depositing SiO₂ with a thickness of 500 nm on a side wall of the blue light-emitting unit by ALD or PECVD, and then forming a first passivation layer by photoetching and dry etching;
S22: depositing one or more of ITO, Mg, Ag, Au, Al, Cu, Cr, Ti, and Ni of 50 nm-1000 nm on a top surface of the LED blue light-emitting unit by sputter as a transparent cathode layer for the LED blue light-emitting unit;
S23: depositing one or more of a distributed bragg reflector (DBR), an omni-directional reflector (ODR), Mg, Ag, Au, Al, Cu, Cr, Ti, and Ni on a surface of the transparent cathode layer as a reflective layer, and performing photo and etching processes in such a way that a length of the reflective layer is lower than a length of the LED blue light-emitting unit by about 0.5μm-30 μm;
S24: respectively disposing reflective lenses on left and right sides of the LED blue light-emitting unit, where each reflective lens can be formed by etching silicon oxynitride and then depositing a reflective metal on the surface; when light emitted by the LED blue light-emitting unit is reflected between an anode of the LED blue light-emitting unit and the reflective layer until the light is transmitted to surfaces of the reflective lenses, enabling an incident light to emit from top surfaces in parallel by the reflective lenses;
S25, forming SiO₂ of 50 nm-100 nm on a surface of the reflective layer by PECVD, a photo process, and an etching process;
S26: depositing one or more of metals Mg, Ag, Au, Al, Cu, Cr, Ti, and Ni of 0.5 μm-2 μm on a periphery top surface of the cathode layer of the LED blue light-emitting unit by photo, deposition, etching, etc. to form a cathode of the LED blue light-emitting unit;
S27: depositing one or more of Mg, Ag, Au, Al, Cu, Cr, Ti, and Ni of 0.5 μm-2 μm on a surface of SiO₂ by photo, deposition, etching, etc. to respectively form an anode of the quantum dot first light-emitting unit and an anode of the quantum dot second light-emitting unit, and allowing the anode of the quantum dot first light-emitting unit and the anode of the quantum dot second light-emitting unit to be respectively connected with tungsten holes in two sides of the LED blue light-emitting unit;
S28: depositing SiO₂ having a thickness of 500 nm by ALD or PECVD, then removing the SiO₂ layer at a position of the anode of the quantum dot first light-emitting unit, and a position of the anode of the quantum dot second light-emitting unit by photoetching and dry etching, and only covering positions other than the quantum dot first light emitting unit and the quantum dot second light-emitting unit;
S29: depositing PEDOT:PSS on a surface of the anode of the quantum dot first light-emitting unit, and a surface of the anode of the quantum dot second light-emitting unit by a solution spin coating method or a vacuum evaporation process to form a hole injection layer having a thickness of 30 nm, and forming a hole injection layer of the first light-emitting unit and a hole injection layer of the second light-emitting unit;
S210: depositing TFB on the hole injection layer by a solution method or a vacuum evaporation process to form a hole transport layer having a thickness of 30 nm, and forming a hole transport layer of the first light-emitting unit and a hole transport layer of the second light-emitting unit;
S211: depositing DICTRz:CdSe/CdS quantum dots (red quantum dots having an emission wavelength of 630 nm) at a position of the quantum dot first light-emitting unit or a position of the quantum dot second light-emitting unit on the hole transport layer by a solution spin coating method or a vacuum evaporation process to form a quantum dot light-emitting layer having a thickness of 40 nm;
S212: depositing CdSe/CdS or InP quantum dots (green quantum dots having an emission wavelength of 540 nm) at a position of the quantum dot second light-emitting unit or a position of the quantum dot first light-emitting unit on the hole transport layer by a solution spin coating method or a vacuum evaporation process to form a quantum dot light-emitting layer having a thickness of 40 nm;
S213: depositing ZnO on the light-emitting layer by a solution method or a vacuum evaporation process to form an electron transport layer having a thickness of 30 nm; and
S214, depositing a transparent conductive thin film ITO having a thickness of 20 nm -1000 nm on the whole CMOS wafer substrate and the quantum dot first light-emitting unit, the quantum dot second light-emitting unit, the cathode of the LED blue light-emitting unit and a cathode ring on the wafer substrate by adopting a sputter process, so that the cathode ring can simultaneously supply power to the LED blue light-emitting unit, the quantum dot first light-emitting unit, and the quantum dot second light-emitting unit to form a common cathode.

### BRIEF DESCRIPTION OF FIGURES

The disclosure will be further described below in detail with reference to the accompanying drawings and specific embodiments.

FIG. 1 shows a schematic cross-sectional view of a quantum dot hybrid integrated multi-color display according to Embodiment 1 of the disclosure.

FIG. 2 shows another schematic cross-sectional view of a quantum dot hybrid integrated multi-color display according to Embodiment 1 of the disclosure.

FIG. 3 shows a schematic top view of a stack structure of a quantum dot hybrid integrated multi-color display according to Embodiment 2 of the disclosure.

FIG. 4 shows a schematic cross-sectional view along BB′ in FIG. 3.

FIG. 5 shows a schematic cross-sectional view along AA′ in FIG. 3.

FIG. 6 shows a schematic structural diagram of a quantum dot electroluminescent unit.

Reference signs in the above figures are respectively:

1—CMOS wafer substrate; 2—anode via; 3—LED blue light-emitting unit; 4—quantum dot first light-emitting unit; 401—anode of first light-emitting unit; 402—hole injection layer of first light-emitting unit; 403—hole transport layer of first light-emitting unit; 404—quantum dot first light-emitting layer; 405—electron transport layer of first light-emitting unit; 406—cathode layer of first light-emitting unit; 5—quantum dot second light-emitting unit; 501—anode of second light-emitting unit; 502—hole injection layer of second light-emitting unit; 503—hole transport layer of second light-emitting unit; 504—quantum dot second light-emitting layer; 505—electron transport layer of second light-emitting unit; 506—cathode layer of second light-emitting unit; 6—filling layer; 7—cover glass; 8—reflective lens; 9—passivation layer; 10—cathode of LED blue light-emitting unit; and 11—reflective layer.

### DETAILED DESCRIPTION

In the disclosure, it needs to be understood that the terms “length”, “width”, “upper”, “lower”, “front”, “rear”, “left”, “right”, “vertical”, “horizontal”, “top”, “bottom”, “inner”, “outer”, “clockwise”, “counterclockwise”, “axial”, “planar direction”, “circumferential direction”, and the like indicate an orientation or positional relationship based on the orientation or positional relationship shown in the drawings, and are only for ease of description of the disclosure and for simplicity of description, and are not intended to indicate or imply that the device or element referred to must have a particular orientation, and be constructed and operate in a particular orientation, and therefore cannot be construed as limiting the disclosure.

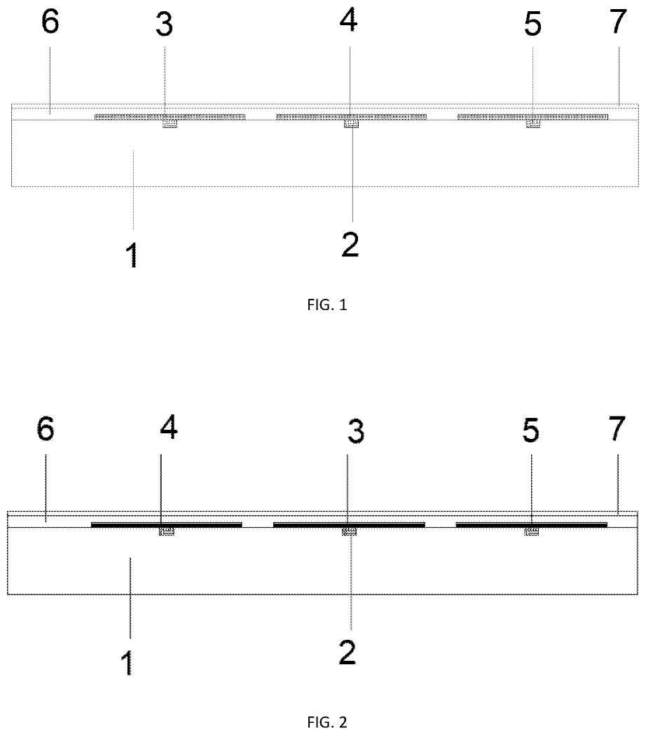

As shown in FIGS. 1 to 6, a quantum dot hybrid integrated multi-color display includes a CMOS wafer substrate 1, anode vias 2, and a light-emitting unit. Where tungsten holes are formed in the CMOS wafer substrate 1, the anode vias 2 are formed in the CMOS wafer substrate 1, and the anode vias 2 are electrically connected with a driving circuit in the CMOS wafer substrate 1 through the tungsten holes. The anode via 2 is a blind via that starts on a surface of the CMOS wafer substrate, that is, the anode via 2 starts on the surface of the CMOS wafer substrate but does not pass all the way through. The light-emitting unit is disposed on surface of the anode via 2 in the CMOS wafer substrate 1, and a driving current signal is provided to the light-emitting unit through the anode via 2. The quantum dot hybrid integrated multi-color display further includes a filling layer 6 and a cover glass 7. The filling layer 6 is formed by OC glue and coats a surface of the CMOS wafer substrate 1 and a surface of the light-emitting unit, and the cover glass 7 is used for covering to seal the whole device. In the embodiments of the disclosure, the problem of micro-LED colorization and the disadvantages of immature technology about the lifetime and efficiency of quantum dot blue material are avoided by using quantum dots in combination with blue LEDs. The quantum dot hybrid integrated multi-color display is simple in structure, convenient in use, high in manufacturing yield, and good in luminous effect.

The light-emitting unit includes an LED blue light-emitting unit 3, a quantum dot first light-emitting unit 4 and a quantum dot second light-emitting unit 5. The quantum dot first light-emitting unit 4 is configured to emit a green light and the quantum dot second light-emitting unit 5 is configured to emit a red light, or the quantum dot first light-emitting unit 4 is configured to emit a red light and the quantum dot second light-emitting unit 5 is configured to emit a green light. Alternatively, only the quantum dot first light-emitting unit 4 and the LED blue light-emitting unit 3 are arranged to jointly form a two-color light-emitting unit, and the quantum dot first light-emitting unit 4 is configured to emit a green light or red light. Alternatively, only the quantum dot second light-emitting unit 5 and the LED blue light-emitting unit 3 are arranged to jointly form a two-color light-emitting unit, and the quantum dot second light-emitting unit 5 is configured to emit a green light or red light.

### EMBODIMENT 1

An LED blue light-emitting unit 3, a quantum dot first light-emitting unit 4 and a quantum dot second light-emitting unit 5 are respectively disposed on surfaces of anode vias 2 which are formed side by side in a CMOS wafer substrate 1, and a spacing is formed between the LED blue light-emitting unit 3, the quantum dot first light-emitting unit 4 and the quantum dot second light-emitting unit 5. The LED blue light-emitting unit 3, the quantum dot first light-emitting unit 4, the quantum dot second light-emitting unit 5 each has a size of 0.1 μm-10 μm, and the spacing between the LED blue light-emitting unit 3, the quantum dot first light-emitting unit 4, and the quantum dot second light-emitting unit 5 is 0.01 μm-10 μm. A transparent conductive thin film Indium Tin Oxide (ITO) is deposited on the whole CMOS wafer substrate 1, as well as the LED blue light-emitting unit 3, the quantum dot first light-emitting unit 4, and the quantum dot second light-emitting unit 5 to form a common cathode. One or more of metals Mg, Ag, Au, Al, Cu, Cr, and Ti are deposited on a surface of the transparent conductive thin film ITO in a region between the LED blue light-emitting unit 3, the quantum dot first light-emitting unit 4, and the quantum dot second light-emitting unit 5 to form one or more metal layers as interconnecting electrodes.

Specifically, a quantum dot hybrid integrated multi-color display includes a CMOS wafer substrate 1. Anode vias 2 are formed in the CMOS wafer substrate 1. The anode via 2 is a blind via that starts on a surface of the CMOS wafer substrate (which does not pass all the way through). A driving current signal can be provided to a light-emitting unit through the anode via 2. An LED blue light-emitting unit 3, a quantum dot first light-emitting unit 4 and a quantum dot second light-emitting unit 5 are respectively disposed on surfaces of the anode vias 2 which are formed side by side. Here, the quantum dot first light-emitting unit 4 can be configured to emit a green light, and the quantum dot second light-emitting unit 5 can be configured to emit a red light; or the quantum dot first light-emitting unit 4 can be configured to emit a red light, and the quantum dot second light-emitting unit 5 can be configured to emit a green light to achieve a full color display effect. Likewise, only the quantum dot first light-emitting unit 4 and the LED blue light-emitting unit 3 can be arranged to jointly form a two-color light-emitting unit, or only the quantum dot second light-emitting unit 5 and the LED blue light-emitting unit 3 can be arranged to jointly form a two-color light-emitting unit.

A manufacturing method for the quantum dot hybrid integrated multi-color display includes: providing a CMOS wafer substrate 1, where anode vias 2 are formed in the CMOS wafer substrate 1, the anode vias 2 are blind vias that starts on a surface of the CMOS wafer substrate, and a driving current signal can be supplied to a light-emitting unit through the anode vias 2, and typically the anode vias 2 are tungsten holes; and providing a blue LED epitaxial wafer, where a material of a LED epitaxial wafer substrate is a common material for epitaxial growth, including silicon, sapphire, gallium nitride, silicon carbide, and the like. The steps of a specific manufacturing method are as follows:
S1: Ti/Pt/Au metal layers are deposited on a surface with tungsten holes of the CMOS wafer substrate 1, a thickness of each corresponding metal layer being 20 nm/50 nm/1000 nm, respectively, and metal bonds are formed on the CMOS wafer substrate 1; ITO/Cr/Al/Pt/Au metal layers are deposited on a surface of the blue LED epitaxial wafer, a thickness of each corresponding metal layer being 50 nm/20 nm/200 nm/50 nm/1000 nm, respectively, and metal bonds are formed on the blue LED epitaxial wafer; the CMOS wafer substrate 1 and the blue LED epitaxial wafer are bonded, the LED epitaxial wafer substrate is removed, and pixel patterning is performed through photoetching and etching to form a silicon-based CMOS wafer with a blue light-emitting unit 3;
Ti/Pt/Au (20 nm/50 nm/1000 nm) metal layers on the surface of the CMOS wafer substrate are etched by an Ion Beam Etch (IBE) process, and only metal layers located at positions of the LED blue light-emitting unit 3, the quantum dot first light-emitting unit 4, and the quantum dot second light-emitting unit 5 are left; here, each light-emitting unit has a size of 0.1 μm-10 μm, and a spacing between the light-emitting units is 0.01 μm-10 μm;

SiO₂ having a thickness of 500 nm is deposited on a side wall of the blue light-emitting unit 3 by atomic layer deposition (ALD) or Plasma Enhanced Chemical Vapor Deposition (PECVD); and a first passivation layer 9 is formed by photoetching and dry etching;
S2: ITO is deposited by a sputter process, an ITO layer is formed above metals at positions where the quantum dot first light-emitting unit 4 and the quantum dot second light-emitting unit 5 are located by photo and etching processes; in order to further improve the brightness of the quantum dot first light-emitting unit 4 and the quantum dot second light-emitting unit 5, a metal having a high reflectivity such as Ag and Al, which has a thickness of 50-1000 nm, can be deposited before depositing the ITO layer;
S3: PEDOT:PSS is deposited on a surface of the ITO layer by a solution spin coating method or a vacuum evaporation process to form a hole injection layer having a thickness of 30 nm, where PEDOT:PSS refers to a high molecular polymer composed of PEDOT and PSS; and PEDOT is a polymer of EDOT (a 3,4-ethylenedioxythiophene monomer), and PSS is polystyrene sulfonate;
S4: TFB (1,2,4,5-tetrakis(trifluoromethyl)benzene) is deposited on the hole injection layer by a solution spin coating method or a vacuum evaporation process to form a hole transport layer having a thickness of 30 nm;
S5: DICTRz:CdSe/CdS quantum dots (red quantum dots having an emission wavelength of 620 nm-640 nm) is deposited at a position of the quantum dot first light-emitting unit 4 or a position of the quantum dot second light-emitting unit 5 on the hole transport layer by a solution spin coating method or a vacuum evaporation process to form a quantum dot light-emitting layer having a thickness of 40 nm, where DICTRz is 12-(4,6-diphenyl-1,3,5-triazin-2-yl)-11-phenylindolo[2,3-a]carbazole, CdSe is cadmium selenide and CdS is cadmium sulfide;
S6: CdSe/CdS or InP quantum dots (green quantum dots having an emission wavelength of 530 nm-550 nm) are deposited at a position of the quantum dot second light-emitting unit 5 or a position of the quantum dot first light-emitting unit 4 on the hole transport layer by a solution spin coating method or a vacuum evaporation process to form a quantum dot light-emitting layer having a thickness of 40 nm, where CdSe is cadmium selenide, CdS is cadmium sulfide, and InP is indium phosphide;
S7: ZnO is deposited on the light-emitting layer by a solution spin coating method or a vacuum evaporation process to form an electron transport layer having a thickness of 30 nm;
S8: substances deposited in subsequent processes of S2 on the surface of the LED blue light-emitting unit are removed, and substances deposited between the LED blue light-emitting unit 3, the quantum dot first light-emitting unit 4, and the quantum dot second light-emitting unit 5 are synchronously removed, via photoetching and an organic solvent chemical etching method, thereby forming the quantum dot first light-emitting unit 4 and the quantum dot second light-emitting unit 5; specifically, materials deposited in S2-S7 on the surface of the LED blue light-emitting unit are removed, and materials deposited in S2-S7 between the LED blue light-emitting unit 3, the quantum dot first light-emitting unit 4, and the quantum dot second light-emitting unit 5 are also removed synchronously, via photoetching and the organic solvent chemical etching method;
S9: a transparent conductive thin film ITO having a thickness of 20 nm-1000 nm is deposited via a sputter process to cover surfaces of the blue light-emitting unit 3, the quantum dot first light-emitting unit 4, and the quantum dot second light-emitting unit 5 to form a common cathode;
S10: one or more metals such as Mg, Ag, Au, Al, Cu, Cr, and Ti is further deposited on a surface of ITO in a region between the LED blue light-emitting unit 3, the quantum dot first light-emitting unit 4, and the quantum dot second light-emitting unit 5 to form one or more metal layers as interconnecting electrodes, in order to enhance the conductivity of the common cathode ITO while not affecting the light output of each light-emitting unit; and
S11: the wafer surface is coated with a filling layer 6 formed by OC glue by spin coating or dispensing, and then the whole device is sealed and protected with a cover glass 7.

### EMBODIMENT 2

An LED blue light-emitting unit 3 is disposed on a surface of an anode via 2 in the CMOS wafer substrate 1, a passivation layer is deposited on a side wall of the LED blue light-emitting unit 3 via Plasma Enhanced Chemical Vapor Deposition (PECVD) or atomic layer deposition (ALD), a quantum dot first light-emitting unit 4 and a quantum dot second light-emitting unit 5 are disposed above the LED blue light-emitting unit 3, and a spacing is formed between the quantum dot first light-emitting unit 4 and the quantum dot second light-emitting unit 5. The spacing between the quantum dot first light-emitting unit 4 and the quantum dot second light-emitting unit 5 is 0.01 μm-0.3 μm, the LED blue light-emitting unit 3 has a size of 0.1 μm-30 μm, and the quantum dot first light-emitting unit 4 and the quantum dot second light-emitting unit 5 each has a size of 0.1 μm-20 μm.

One or more of ITO, Mg, Ag, Au, Al, Cu, Cr, Ti, and Ni are deposited on a top surface of the LED blue light-emitting unit 3 to form a transparent cathode layer for the LED blue light-emitting unit 3, one or more of distributed bragg reflector (DBR), omni-directional reflector (ODR), Mg, Ag, Au, Al, Cu, Cr, Ti, and Ni are deposited on a surface of the cathode layer as a reflective layer 11, a length of the reflective layer 11 is less than a length of the LED blue light-emitting unit 3, the quantum dot first light-emitting unit 4 and the quantum dot second light-emitting unit 5 are located on a top surface of the reflective layer 11, and an anode of the quantum dot first light-emitting unit 4 and an anode of the quantum dot second light-emitting unit 5 each are electrically connected with the anode via 2 in the CMOS wafer substrate 1.

One or more of ITO, Mg, Ag, Au, Al, Cu, Cr, Ti, and Ni of 0.5 μm-2 μm are deposited on a periphery top surface of the LED blue light-emitting unit to form a cathode 10 of the LED blue light-emitting unit, and reflective lenses 8 are respectively arranged at left and right sides of the LED blue light-emitting unit 3. A transparent conductive thin film ITO is deposited on the whole CMOS wafer substrate 1 and the quantum dot first light-emitting unit 4, the quantum dot second light-emitting unit 5, and the cathode 10 of the LED blue light-emitting unit as a common cathode, and one or more of metals Mg, Ag, Au, Al, Cu, Cr, and Ti are deposited on a surface of the transparent conductive thin film ITO between the quantum dot first light-emitting unit 4 and the quantum dot second light-emitting unit 5 to form one or more metal layers as interconnecting electrodes.

Specifically, a quantum dot hybrid integrated multi-color display includes a CMOS wafer substrate 1, anode vias 2 are formed in the CMOS wafer substrate 1, the anode vias 2 is a blind via that starts on a surface of the CMOS wafer substrate (which does not pass all the way through), a driving current signal can be provided to a light-emitting unit through the anode via 2. An LED blue light-emitting unit 3 is disposed on a surface of the anode via 2, and a passivation layer is deposited on a side wall of the LED blue light-emitting unit 3 by PECVD or ALD. The quantum dot first light-emitting unit 4 and the quantum dot second light-emitting unit 5 are disposed above the LED blue light-emitting unit 3. The LED blue light-emitting unit 3, the quantum dot first light-emitting unit 4, and the quantum dot second light-emitting unit 5 are respectively arranged through side-by-side anode vias 2 for separate control to form an AM quantum dot hybrid integrated multi-color display. Or, only the quantum dot first light-emitting unit 4 or the quantum dot second light-emitting unit 5 can be disposed on the surface of the LED blue light-emitting unit 3 to form a two-color AM quantum dot hybrid integrated display. The quantum dot first light-emitting unit 4 can be configured to emit a green light, and the quantum dot second light-emitting unit 5 can be configured to emit a red light; or the quantum dot first light-emitting unit 4 can be configured to emit a red light, and the quantum dot second light-emitting unit 5 can be configured to emit a green light, to achieve a full color display effect. Likewise, only the quantum dot first light-emitting unit 4 and the LED blue light-emitting unit 3 can be arranged to jointly form a two-color light-emitting unit, or only the quantum dot second light-emitting unit 5 and the LED blue light-emitting unit 3 can be arranged to jointly form a two-color light-emitting unit.

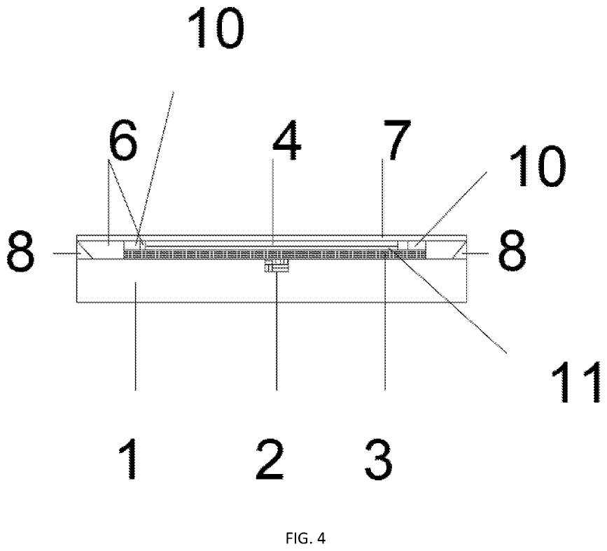

In FIG. 4, the blue light-emitting unit 3 is bonded to surfaces of the anode vias 2 in the CMOS wafer substrate through a metal bonding process. Here, bonded metal includes one or more metals such as Mg, Ag, Au, Al, Cu, Cr, Ti, and Ni to form one or more metal layers as an anode of the LED blue light-emitting unit; one or more of ITO, Mg, Ag, Au, Al, Cu, Cr, Ti, and Ni are deposited on a top surface of the LED blue light-emitting unit 3 as a transparent cathode layer for the LED blue light-emitting unit 3 in a sputter process, and one or more of DBR, ODR, Mg, Ag, Au, Al, Cu, Cr, Ti, and Ni are deposited on a surface of the cathode layer as a reflective layer 11, where a length of the reflective layer 11 is less than a length of the LED blue light-emitting unit 3.

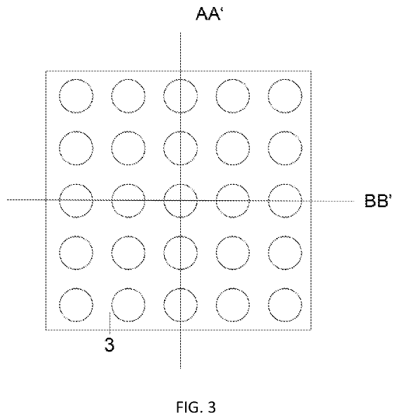

Reflective lenses 8 are respectively arranged on left and right sides of the LED blue light-emitting unit 3, and when light emitted from the LED blue light-emitting unit is reflected between an anode of the LED blue light-emitting unit and the reflective layer 11 until the light is transmitted to surfaces of the reflective lenses 8, the reflective lenses 8 enable an incident light to emit from its top surfaces in parallel. The quantum dot first light-emitting unit 4 and the quantum dot second light-emitting unit 5 are located on or above the top surface of the reflective layer 11, and if the reflective layer 11 is conductive metal, an insulating medium between the reflective layer 11 and the quantum dot light-emitting units can be an organic polymer, SiN, SiO, or the like. In a direction BB′ in FIG. 3, as shown in FIG. 4, one or more of ITO, Mg, Ag, Au, Al, Cu, Cr, Ti, and Ni of 0.5 μm-2 μm are deposited on a periphery top surface of the LED blue light-emitting unit to form a cathode 10 of the LED blue light-emitting unit.

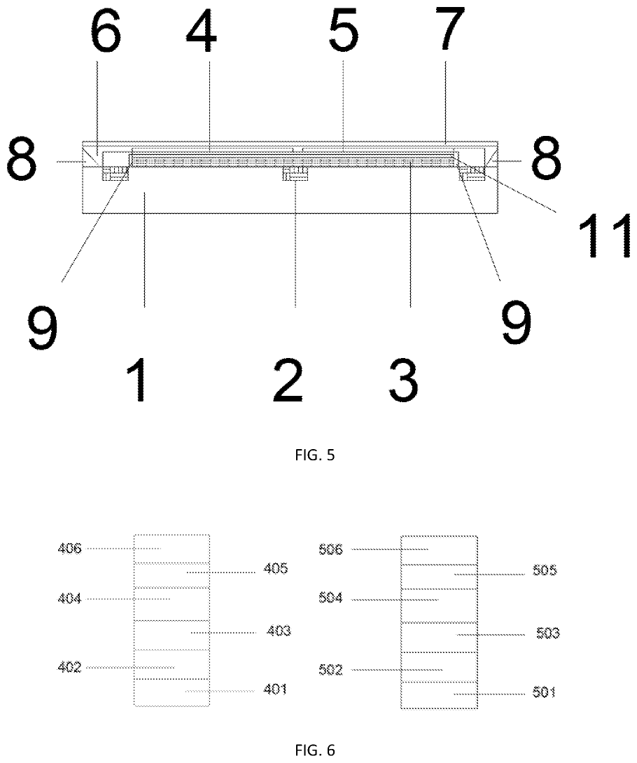

In a direction AA′ in FIG. 3, as shown in FIG. 5, the quantum dot first light-emitting unit 4 and the quantum dot second light-emitting unit 5 are respectively located above the top surface of the reflective layer 11, and an anode of the quantum dot first light-emitting unit 4 and an anode of the quantum dot second light-emitting unit 5 are respectively electrically connected with anode vias 2 in the wafer substrate. Here, a size of an area occupied by the quantum dot first light-emitting unit 4 and a size of an area occupied by the quantum dot second light-emitting unit 5 can be set according to requirements. For example, an area of a green light-emitting unit is ⅓ of an area of the reflective layer 11, and an area of a red light-emitting unit is ⅔ of the area of the reflective layer 11. Then ITO having a thickness of 20 nm-1000 nm is deposited on the whole CMOS wafer substrate 1 and the quantum dot first light-emitting unit 4, the quantum dot second light-emitting unit 5, and the cathode 10 the LED blue light-emitting unit as a common cathode, which connects the cathode of the LED blue light-emitting unit, the quantum dot first light-emitting unit 4, and the quantum dot second light-emitting unit 5 with a cathode ring on the wafer substrate. One or more metals such as Mg, Ag, Au, Al, Cu, Cr, and Ti can be further deposited on a surface of ITO between the light-emitting units to form one or more metal layers as interconnecting electrodes to enhance the conductivity of the common cathode ITO while not affecting the light output of each light-emitting unit. The wafer surface is coated with a filling layer 6 formed by OC glue by spin coating or dispensing on the surface of the cathode layer, and then the whole device is sealed and protected with a cover glass 7.

The quantum dot first light-emitting unit 4 includes an anode 401 of the first light-emitting unit, a hole injection layer 402 of the first light-emitting unit, a hole transport layer 403 of the first light-emitting unit, a quantum dot first light-emitting layer 404, an electron transport layer 405 of the first light-emitting unit, and a cathode layer 406 of the first light-emitting unit which are sequentially disposed from bottom to top. The quantum dot second light-emitting unit 5 includes an anode 501 of the second light-emitting unit, a hole injection layer 502 of the second light-emitting unit, a hole transport layer 503 of the second light-emitting unit, a quantum dot second light-emitting layer 504, an electron transport layer 505 of the second light-emitting unit, and a cathode layer 506 of the second light-emitting unit which are sequentially disposed from bottom to top. Here, the hole injection layer and the hole transport layer of the light-emitting unit may or may not be separated.

A manufacturing method for the quantum dot hybrid integrated multi-color display includes: providing a CMOS wafer substrate 1, where anode vias 2 are formed in the CMOS wafer substrate 1, the anode vias 2 are blind vias that start on a surface of the CMOS wafer substrate, a driving current signal can be supplied to light-emitting units through the anode vias 2, and the anode vias 2 are electrically connected with a driving circuit in the CMOS wafer substrate 1 through tungsten holes; and providing a blue LED epitaxial wafer, where a material of a LED epitaxial wafer substrate is a common material for epitaxial growth, including silicon, sapphire, gallium nitride, silicon carbide, and the like. Specific manufacturing steps are as follows:
S21: Ti/Pt/Au metal layers are deposited on a surface with tungsten holes of the CMOS wafer substrate 1, a thickness of each corresponding metal layer being 20 nm/50 nm/1000 nm, respectively, and metal bonds are formed on the CMOS wafer substrate 1; ITO/Cr/Al/Pt/Au metal layers are deposited on a surface of the blue LED epitaxial wafer, a thickness of each corresponding layer being 50 nm/20 nm/200 nm/50 nm/1000 nm, respectively, and metal bonds are formed on the blue LED epitaxial wafer; the CMOS wafer substrate 1 and the blue LED epitaxial wafer are bonded, the LED epitaxial wafer substrate is removed, and pixel patterning is performed through photoetching and etching to form a silicon-based CMOS wafer with a blue light-emitting unit 3;
Ti/Pt/Au (20 nm/50 nm/1000 nm) metal layers on the surface of the CMOS wafer substrate are etched by an IBE process, and only metals located at a position of the LED blue light-emitting unit 3 are left, where each light-emitting unit has a size of 0.1 μm-30 μm; and a spacing between the light-emitting units is 0.01 μm-5 μm;
SiO₂ having a thickness of 500 nm is deposited on a side wall of the blue light-emitting unit 3 by ALD or PECVD, and a first passivation layer is formed by photoetching and dry etching;
S22: one or more of ITO, Mg, Ag, Au, Al, Cu, Cr, Ti, and Ni of 50 nm-1000 nm is deposited on a top surface of the LED blue light-emitting unit 3 by sputter as a transparent cathode layer for the LED blue light-emitting unit 3;
S23: one or more of DBR, ODR, Mg, Ag, Au, Al, Cu, Cr, Ti, and Ni are deposited on a surface of the transparent cathode layer as a reflective layer 11, and photo and etching processes are performed so that a length of the reflective layer 11 is lower than a length of the LED blue light-emitting unit 3 by about 0.5 μm-30 μm, so as to minimize the loss of an area of a light-emitting layer during a subsequent deposition of a cathode 10 of the LED blue light-emitting unit;
S24: reflective lenses 8 are respectively formed on left and right sides of the LED blue light-emitting unit 3, where each reflective lens 8 can be formed by etching silicon oxynitride and then depositing a reflective metal on the surface; it should be noted that the manufacturing method of the reflective lenses 8 can refer to methods in the related art, which will not be described in detail; here, when light emitted from the LED blue light-emitting unit is reflected between an anode of the LED blue light-emitting unit and the reflective layer 11 until the light is transmitted to surfaces of the reflective lenses 8, the reflective lenses 8 enable an incident light to emit from top surfaces in parallel;
S25: SiO₂ of 50-100 nm is manufactured on a surface of the reflective layer 11 by PECVD, a photo process, and an etching process;
S26: one or more of Mg, Ag, Au, Al, Cu, Cr, Ti, and Ni of 0.5 μm-2 μm are deposited on a periphery top surface of the cathode layer of the LED blue light-emitting unit by photo, deposition, etching, etc. to form a cathode 10 of the LED blue light-emitting unit in the direction BB′ of FIG. 3;
S27: one or more of Mg, Ag, Au, Al, Cu, Cr, Ti, and Ni of 0.5 μm-2 μm are deposited on a surface of SiO₂ by photo, deposition, etching, etc. in the direction AA′ of FIG. 3 to form an anode of the quantum dot first light-emitting unit 4 and an anode of the quantum dot second light-emitting unit 5 respectively, where the anode of the quantum dot first light-emitting unit 4 and the anode of the quantum dot second light-emitting unit 5 are respectively connected with tungsten holes at two sides of the LED blue light-emitting unit 3; where a size of an area occupied by the quantum dot first light-emitting unit 4 and a size of an area occupied by the quantum dot second light-emitting unit 5 can be set according to requirements, for example, an area of a green light-emitting unit is ⅓ of an area of the reflective layer 11, and an area of a red light-emitting unit is ⅔ of the area of the reflective layer 11; and the anode of the quantum dot first light-emitting unit 4 and the anode of the quantum dot second light-emitting unit 5 are disconnected;
S28: SiO₂ having a thickness of 500 nm is deposited by ALD or PECVD, then the SiO₂ layer at a position of the anode of the quantum dot first light-emitting unit 4, and a position of the anode of the quantum dot second light-emitting unit 5 is removed by photoetching and dry etching, and only positions other than the quantum dot first light emitting unit 4 and the quantum dot second light-emitting unit 5 are covered by SiO₂;
S29: PEDOT:PSS is deposited on a surface of the anode of the quantum dot first light-emitting unit 4, and a surface of the anode of the quantum dot second light-emitting unit 5 by a solution spin coating method or a vacuum evaporation process to form a hole injection layer having a thickness of 30 nm. PEDOT:PSS refers to a high molecular polymer composed of PEDOT and PSS, PEDOT is a polymer of EDOT (a 3,4-ethylenedioxythiophene monomer), PSS is polystyrene sulfonate. A hole injection layer 402 of the first light-emitting unit and a hole injection layer 502 of the second light-emitting unit are formed, where the hole injection layer 402 the first light-emitting unit and the hole injection layer 502 of the second light-emitting unit may be connected or disconnected;
S210: TFB (1,2,4,5-tetrakis(trifluoromethyl)benzene) is deposited on the hole injection layer by a solution spin coating method or a vacuum evaporation process to form a hole transport layer having a thickness of 30 nm, and a hole transport layer 403 of the first light-emitting unit and a hole transport layer 503 of the second light-emitting unit are formed, where the hole transport layer 403 of the first light-emitting unit and the hole transport layer 503 of the second light-emitting unit may be connected or disconnected;
S211: DICTRz:CdSe/CdS quantum dots (red quantum dots having an emission wavelength of 630 nm) is deposited at a position of the quantum dot first light-emitting unit 4 or a position of the quantum dot second light-emitting unit 5 on the hole transport layer by a solution spin coating method or a vacuum evaporation process to form a quantum dot light-emitting layer having a thickness of 40 nm, where DICTRz refers to 12-(4,6-diphenyl-1,3,5-triazin-2-yl)-11-phenylindolo[2,3-a]carbazole, CdSe is cadmium selenide and CdS is cadmium sulfide;
S212: CdSe/CdS or InP quantum dots (green quantum dots having an emission wavelength of 540 nm) are deposited at a position of the quantum dot second light-emitting unit 5 or a position of the quantum dot first light-emitting unit 4 on the hole transport layer by a solution spin coating method or a vacuum evaporation process to form a quantum dot light-emitting layer having a thickness of 40 nm, where CdSe is cadmium selenide, CdS is cadmium sulfide, and InP is indium phosphide;
S213: ZnO is deposited on the light-emitting layer by a solution spin coating method or a vacuum evaporation process to form an electron transport layer having a thickness of 30 nm, the quantum dot first light-emitting unit 4 and the quantum dot second light-emitting unit 5 being disconnected;
S214: a transparent conductive thin film ITO having a thickness of 20 nm-1000 nm (not shown in the figure) is deposited on the whole CMOS wafer substrate 1 and the quantum dot first light-emitting unit 4, the quantum dot second light-emitting unit 5, the cathode 10 of the LED blue light-emitting unit and a cathode ring (not shown in the figures) on the wafer substrate by a sputter process, so that the cathode ring can simultaneously supply power to the LED blue light-emitting unit 3, the quantum dot first light-emitting unit 4, and the quantum dot second light-emitting unit 5 to form a common cathode;
S215: one or more metals such as Mg, Ag, Au, Al, Cu, Cr, and Ti can be further deposited on a surface of ITO between the quantum dot first light-emitting unit 4 and the quantum dot second light-emitting unit 5 to form one or more metal layers as interconnecting electrodes to enhance the conductivity of the common cathode ITO while not affecting the light output of each light-emitting unit; and
S216: the wafer surface is coated with a filling layer 6 formed by OC glue by spin coating or dispensing on the surface of the cathode layer, and then the whole device is sealed and protected with a cover glass 7.

The advantages of adopting the technical solution of the embodiments of the disclosure are as follows.

In the embodiments of the disclosure, the problem of micro-LED colorization and the disadvantages of immature technology about the lifetime and efficiency of quantum dot blue material are avoided by using quantum dots in combination with blue LEDs; the quantum dot hybrid integrated multi-color display provided by the embodiments of the disclosure is simple in structure, convenient in use, high in manufacturing yield, and good in luminous effect; further, a quantum dot hybrid integrated multi-color display of a vertical structure is provided, which can further improve the PPI of a display.

Moreover, the problem of low efficiency of existing GaN red light is overcome, and high efficiency display of an inorganic LED microdisplay device is realized by integrating blue LEDs of a mature inorganic GaN system with the red and green quantum dot light-emitting system technology to form a colorized microdisplay device.

The disclosure has been exemplarily described above with reference to the accompanying drawings, obviously, the specific implementations of the disclosure are not limited by the above-described embodiments, and as long as various modifications are made by using the technical solutions of the disclosure, or other applications directly use the concepts and technical solutions of the disclosure without modification, they all fall within the scope of protection of the disclosure.

What is claimed is:

1. A quantum dot hybrid integrated multi-color display, comprising:
a complementary metal oxide semiconductor (CMOS) wafer substrate;
a anode via; and
a light-emitting unit;
wherein
the CMOS wafer substrate is provided with a tungsten hole formed therein;
the anode via is formed in the CMOS wafer substrate, the anode via is electrically connected with a driving circuit in the CMOS wafer substrate through the tungsten hole, and the anode via is a blind via that starts on a surface of the CMOS wafer substrate;
the light-emitting unit is disposed on a surface of the anode via in the CMOS wafer substrate, and a driving current signal is provided to the light-emitting unit through the anode via.

2. The quantum dot hybrid integrated multi-color display according to claim 1,
wherein the light-emitting unit comprises an LED blue light-emitting unit, a quantum dot first light-emitting unit and a quantum dot second light-emitting unit;
wherein
the quantum dot first light-emitting unit is configured to emit a green light and the quantum dot second light-emitting unit is configured to emit a red light; or
the quantum dot first light-emitting unit is configured to emit a red light and the quantum dot second light-emitting unit is configured to emit a green light;
or
the quantum dot first light-emitting unit and the LED blue light-emitting unit are arranged to jointly form a two-color light-emitting unit, and the quantum dot first light-emitting unit is configured to emit a green light or a red light; or
the quantum dot second light-emitting unit and the LED blue light-emitting unit are arranged to jointly form a two-color light-emitting unit, and the quantum dot second light-emitting unit is set to emit a green light or a red light.

3. The quantum dot hybrid integrated multi-color display according to claim 2, wherein
the quantum dot first light-emitting unit comprises an anode of the first light-emitting unit, a hole injection layer of the first light-emitting unit, a hole transport layer of the first light-emitting unit, a quantum dot first light-emitting layer, an electron transport layer of the first light-emitting unit, and a cathode layer of the first light-emitting unit which are sequentially disposed from bottom to top; and
the quantum dot second light-emitting unit comprises an anode of the second light-emitting unit, a hole injection layer of the second light-emitting unit, a hole transport layer of the second light-emitting unit, a quantum dot second light-emitting layer, an electron transport layer of the second light-emitting unit, and a cathode layer of the second light-emitting unit which are sequentially disposed from bottom to top.

4. The quantum dot hybrid integrated multi-color display according to claim 3, wherein the LED blue light-emitting unit, the quantum dot first light-emitting unit and the quantum dot second light-emitting unit are respectively arranged on surfaces of anode vias which are formed side by side in the CMOS wafer substrate; and
a spacing is formed between the LED blue light-emitting unit, the quantum dot first light-emitting unit and the quantum dot second light-emitting unit.

5. The quantum dot hybrid integrated multi-color display according to claim 4, wherein a transparent conductive thin film indium tin oxide (ITO) is deposited on a whole CMOS wafer substrate and the LED blue light-emitting unit, the quantum dot first light-emitting unit, and the quantum dot second light-emitting unit to form a common cathode; and
one or more of metals Mg, Ag, Au, Al, Cu, Cr, and Ti are deposited on a surface of the transparent conductive thin film ITO in a region between the LED blue light-emitting unit, the quantum dot first light-emitting unit, and the quantum dot second light-emitting unit to form one or more metal layers as interconnecting electrodes.

6. The quantum dot hybrid integrated multi-color display according to claim 3, wherein
the LED blue light-emitting unit is disposed on a surface of the anode via in the CMOS wafer substrate;
a passivation layer is deposited on a side wall of the LED blue light-emitting unit by plasma enhanced chemical vapor deposition (PECVD) or atomic layer deposition (ALD);
the quantum dot first light-emitting unit and the quantum dot second light-emitting unit are disposed above the LED blue light-emitting unit; and
a spacing is formed between the quantum dot first light-emitting unit and the quantum dot second light-emitting unit.

7. The quantum dot hybrid integrated multi-color display according to claim 6, wherein
a transparent cathode layer for the LED blue light-emitting unit is deposited on a top surface of the LED blue light-emitting unit;
a reflective layer is deposited on a surface of the transparent cathode layer, wherein a length of the reflective layer is less than a length of the LED blue light-emitting unit;
the quantum dot first light-emitting unit and the quantum dot second light-emitting unit are disposed on a top surface of the reflective layer; and
an anode of the quantum dot first light-emitting unit and an anode of the quantum dot second light-emitting unit are respectively electrically connected with the anode vias in the CMOS wafer substrate.

8. The quantum dot hybrid integrated multi-color display according to claim 7, wherein
a cathode for the LED blue light-emitting unit is deposited on a periphery top surface of the LED blue light-emitting unit, and reflective lenses are respectively arranged on left and right sides of the LED blue light-emitting unit; and
a transparent conductive thin film ITO is deposited on a whole CMOS wafer substrate, the quantum dot first light-emitting unit, the quantum dot second light-emitting unit, and the cathode of the LED blue light-emitting unit as a common cathode; and
one or more of metals Mg, Ag, Au, Al, Cu, Cr, and Ti are deposited on a surface of the transparent conductive thin film ITO between the quantum dot first light-emitting unit and the quantum dot second light-emitting unit to form one or more metal layers as interconnecting electrodes.

9. The quantum dot hybrid integrated multi-color display according to claim 1, further comprising:
a filling layer formed by OC glue and covering a surface of the CMOS wafer substrate and a surface of the light-emitting unit; and
a cover glass used for covering to seal the display.

10. A manufacturing method for the quantum dot hybrid integrated multi-color display according to claim 1, comprising:
S1: providing a CMOS wafer substrate and a blue LED epitaxial wafer, performing metal bonding on the CMOS wafer substrate and the blue LED epitaxial wafer, removing an LED epitaxial wafer substrate, and performing pixel patterning through photoetching and etching to form a silicon-based CMOS wafer with a blue light-emitting unit; and etching a metal on a surface of the CMOS wafer by an ion beam etching (IBE) process, and leaving metals located at positions of an LED blue light-emitting unit, a quantum dot first light-emitting unit, and a quantum dot second light-emitting unit, wherein each light-emitting unit has a size of 0.1 μm-30 μm, and a spacing between the light-emitting units is 0.01 μm-5 μm;
S2: depositing ITO by a sputter process, and forming an ITO layer above metals at positions where the quantum dot first light-emitting unit and the quantum dot second light-emitting unit are located by photo and etching processes;
S3: depositing PEDOT:PSS on a surface of the ITO layer by a solution spin coating method or a vacuum evaporation process to form a hole injection layer having a thickness of 30 nm;
S4: depositing TFB on the hole injection layer by the solution spin coating method or the vacuum evaporation process to form a hole transport layer having a thickness of 30 nm;
S5: depositing DICTRz:CdSe/CdS quantum dots at a position of the quantum dot first light-emitting unit or a position of the quantum dot second light-emitting unit on the hole transport layer by the solution spin coating method or the vacuum evaporation process to form a quantum dot light-emitting layer having a thickness of 40 nm;
S6: depositing CdSe/CdS or InP quantum dots at a position of the quantum dot second light-emitting unit or a position of the quantum dot first light-emitting unit on the hole transport layer by the solution spin coating method or the vacuum evaporation process to form a quantum dot light-emitting layer having a thickness of 40 nm;
S7: depositing ZnO on the quantum dot light-emitting layer by the solution spin coating method or the vacuum evaporation process to form an electron transport layer having a thickness of 30 nm;
S8: forming the quantum dot first light-emitting unit and the quantum dot second light-emitting unit by removing substances deposited in subsequent steps from S2 on the surface of the LED blue light-emitting unit and synchronously removing substances deposited between the LED blue light-emitting unit, the quantum dot first light-emitting unit, and the quantum dot second light-emitting unit, using photoetching and an organic solvent chemical etching method; and
S9: depositing a transparent conductive thin film ITO having a thickness of 20 nm-1000 nm by the sputter process to cover surfaces of the blue light-emitting unit, the quantum dot first light-emitting unit, and the quantum dot second light-emitting unit to form a common cathode.

11. The manufacturing method for the quantum dot hybrid integrated multi-color display according to claim 10, further comprising:
S10: depositing one or more metals such as Mg, Ag, Au, Al, Cu, Cr, and Ti on a surface of ITO in a region between the LED blue light-emitting unit, the quantum dot first light-emitting unit, and the quantum dot second light-emitting unit to form one or more metal layers as interconnecting electrodes.

12. The manufacturing method for the quantum dot hybrid integrated multi-color display according to claim 11, further comprising:
S11: coating the wafer surface with a filling layer formed by OC glue by spin coating or dispensing, and sealing the display with a cover glass.

13. A manufacturing method for the quantum dot hybrid integrated multi-color display according to claim 6, comprising:
S21: providing a CMOS wafer substrate and a blue LED epitaxial wafer, performing metal bonding on the CMOS wafer substrate and the blue LED epitaxial wafer, removing an LED epitaxial wafer substrate, and performing pixel patterning through photoetching and etching to form a silicon-based CMOS wafer with a blue light-emitting unit; etching a metal on a surface of the CMOS wafer by an IBE process, and leaving a metal located in a region of the LED blue light-emitting unit; and depositing SiO₂ with a thickness of 500 nm on a side wall of the LED blue light-emitting unit by ALD or PECVD, and forming a first passivation layer by photoetching and dry etching;
S22: depositing one or more of ITO, Mg, Ag, Au, Al, Cu, Cr, Ti, and Ni of 50 nm-1000 nm on a top surface of the LED blue light-emitting unit by a sputter process as a transparent cathode layer for the LED blue light-emitting unit;
S23: depositing one or more of a distributed bragg reflector (DBR), an omni-directional reflector (ODR), Mg, Ag, Au, Al, Cu, Cr, Ti, and Ni on a surface of the transparent cathode layer as a reflective layer, and performing photo and etching processes in such a way that a length of the reflective layer is lower than a length of the LED blue light-emitting unit by about 0.5 μm-30 μm;
S24: respectively disposing reflective lenses on left and right sides of the LED blue light-emitting unit, in such a way that when light emitted by the LED blue light-emitting unit is reflected between an anode of the LED blue light-emitting unit and the reflective layer until the light is transmitted to surfaces of the reflective lenses, an incident light is enabled to emit from top surfaces in parallel by the reflective lenses;
S25: forming SiO₂ of 50-100 nm on a surface of the reflective layer by PECVD, a photo process, and an etching process;
S26: depositing one or more of metals Mg, Ag, Au, Al, Cu, Cr, Ti, and Ni of 0.5 μm-2 μm on a periphery top surface of the cathode layer of the LED blue light-emitting unit by photo, deposition, and etching to form a cathode of the LED blue light-emitting unit;
S27: depositing one or more of Mg, Ag, Au, Al, Cu, Cr, Ti, and Ni of 0.5 μm-2 μm on a surface of SiO₂ by photo, deposition and etching to respectively form an anode of the quantum dot first light-emitting unit and an anode of the quantum dot second light-emitting unit, and allowing the anode of the quantum dot first light-emitting unit and the anode of the quantum dot second light-emitting unit to be respectively connected with tungsten holes in two sides of the LED blue light-emitting unit;
S28: depositing SiO₂ having a thickness of 500 nm by ALD or PECVD, removing the SiO₂ layer at a position of the anode of the quantum dot first light-emitting unit, and a position of the anode of the quantum dot second light-emitting unit by photoetching and dry etching, and covering positions other than the quantum dot first light emitting unit and the quantum dot second light-emitting unit;
S29: depositing PEDOT:PSS on a surface of the anode of the quantum dot first light-emitting unit, and a surface of the anode of the quantum dot second light-emitting unit by a solution spin coating method or a vacuum evaporation process to form a hole injection layer having a thickness of 30 nm, and forming a hole injection layer of the first light-emitting unit and a hole injection layer of the second light-emitting unit;
S210: depositing TFB on the hole injection layer by a solution spin coating method or a vacuum evaporation process to form a hole transport layer having a thickness of 30 nm, and forming a hole transport layer of the first light-emitting unit and a hole transport layer of the second light-emitting unit;
S211: depositing DICTRz:CdSe/CdS quantum dots at a position of the quantum dot first light-emitting unit or a position of the quantum dot second light-emitting unit on the hole transport layer by a solution spin coating method or a vacuum evaporation process to form a quantum dot light-emitting layer having a thickness of 40 nm;
S212: depositing CdSe/CdS or InP quantum dots at a position of the quantum dot second light-emitting unit or a position of the quantum dot first light-emitting unit on the hole transport layer by a solution spin coating method or a vacuum evaporation process to form a quantum dot light-emitting layer having a thickness of 40 nm;
S213: depositing ZnO on the light-emitting layer by a solution spin coating method or a vacuum evaporation process to form an electron transport layer having a thickness of 30 nm; and
S214: depositing a transparent conductive thin film ITO having a thickness of 20 nm-1000 nm on a whole CMOS wafer substrate and the quantum dot first light-emitting unit, the quantum dot second light-emitting unit, the cathode of the LED blue light-emitting unit and a cathode ring on the wafer substrate by a sputter process, to allow the cathode ring to simultaneously supply power to the LED blue light-emitting unit, the quantum dot first light-emitting unit, and the quantum dot second light-emitting unit to form a common cathode.

14. The manufacturing method for the quantum dot hybrid integrated multi-color display according to claim 13, further comprising:
S215: depositing one or more metals such as Mg, Ag, Au, Al, Cu, Cr, and Ti on a surface of ITO between the quantum dot first light-emitting unit and the quantum dot second light-emitting unit to form one or more metal layers as interconnecting electrodes.

15. The manufacturing method for the quantum dot hybrid integrated multi-color display according to claim 14, further comprising:
S216: coating the wafer surface a filling layer formed by OC glue by spin coating or dispensing on the surface of the cathode layer, and sealing the display with a cover glass.
